(19) United States
(12) Patent Application Publication
(10) Pub. No.: US 2026/0281592 A1
(43) Pub. Date: Sep. 17, 2026

(54) CIRCUIT CHIP AND SOLID-STATE IMAGING DEVICE

(71) Applicant: Sony Semiconductor Solutions Corporation, Kanagawa (JP)

(72) Inventors: Jae-Sung AN, Oslo (NO); Naoki KAWAZU, Kanagawa (JP)

(73) Assignee: Sony Semiconductor Solutions Corporation, Kanagawa (JP)

(21) Appl. No.: 19/162,430

(22) PCT Filed: Mar. 4, 2024
(86) PCT No.: PCT/EP2024/055620

§ 371 Date: Sep. 5, 2025

(30) Foreign Application Priority Data
Mar. 17, 2023 (EP) 23162734.0

(51) Int. Cl. H04N 25/79; G01R 31/28; H04N 17/00; H10F 39/00

(52) U.S. Cl. CPC H04N 25/79; G01R 31/2884; H04N 17/002; H10F 39/809

(57) ABSTRACT

A circuit chip includes a first circuit chip contact area configured to be electrically connected to a first pixel chip contact area of a pixel chip. The circuit chip further includes a first signal line electrically connected to the first circuit chip contact area. The circuit chip further includes a first comparator circuit. The first signal line is electrically coupled to a first input of the first comparator circuit. The circuit chip further includes a first test circuit comprising a digital-to-analog converter circuit. The first test circuit is configured to output a test signal at an output of the first test circuit. The circuit chip further includes a first switching element electrically coupled in series between the output of the first test circuit and the first signal line.

The present disclosure relates to a circuit chip and to a solid-state imaging device. More particularly, the present disclosure relates to a circuit chip including a test circuit.

### BACKGROUND

Image sensors in solid-state imaging devices include photoelectric conversion elements generating a photocurrent in proportion to the received radiation intensity. A pixel circuit transforms the small photocurrent generated by the photoelectric conversion element into a voltage signal (pixel output signal) and outputs the pixel output signal on a data line (vertical signal line). A downstream ADC (analog-to-digital converter) converts the analog pixel output signal into a digital pixel value. The ADC may be a ramp compare ADC that includes a comparator and a counter. The comparator compares the pixel output voltage with a voltage ramp and outputs an active comparator signal when the voltage ramp exceeds or falls below the pixel output voltage. The counter counts events that occur at regular intervals in a count period between the start of the voltage ramp and the start of the active comparator signal. The count value at the end of the count period gives the result of the analog-to-digital conversion and defines the digital pixel value.

Before delivery of the image sensors wafer testing is indispensable for identifying functional defects. Reliable identification of functional defects at low testing costs is challenging and requires improved test circuits.

### SUMMARY

The present disclosure provides a circuit chip and a solid-state imaging device with improved test circuits.

To this purpose, a circuit chip includes a first circuit chip contact area configured to be electrically connected to a first pixel chip contact area of a pixel chip. The circuit chip further includes a first signal line electrically connected to the first circuit chip contact area. The circuit chip further includes a first comparator circuit. The first signal line is electrically coupled to a first input of the first comparator circuit. The circuit chip further includes a first test circuit comprising a digital-to-analog converter circuit. The first test circuit is configured to output a test signal at an output of the first test circuit. The circuit chip further includes a first switching element electrically coupled in series between the output of the first test circuit and the first signal line.

A solid-state imaging device includes the circuit chip and a pixel chip stacked over the circuit chip. The pixel chip includes a plurality of pixel circuits arranged in a matrix pattern, and a first vertical signal line. A group of the plurality of pixel circuits is electrically coupled to the first vertical signal line. The first vertical signal line is electrically connected to the first signal line of the circuit chip via the first pixel chip contact area and the first circuit chip contact area.

### BRIEF DESCRIPTION OF THE DRAWINGS

A more complete appreciation of the disclosure and many of the advantages thereof will be readily obtained as the same becomes better understood by reference to the following detailed description when considered in connection with the accompanying drawings, wherein:

FIG. 1 is a simplified circuit diagram depicting an exemplary circuit configuration of a circuit chip according to an embodiment of the present technology.

FIG. 2 is a simplified circuit diagram depicting an exemplary circuit configuration of a circuit chip according to another embodiment of the present technology.

FIG. 3 is a simplified circuit diagram depicting an exemplary circuit configuration of a switching array circuit.

FIGS. 4, 5A and 5B are simplified circuit diagrams depicting exemplary circuit configurations of a circuit chip according to embodiments of the present technology.

FIG. 6 is a simplified diagram depicting an exemplary interconnecting scheme of circuit pads and test circuits.

FIG. 7 is a diagram for illustrating groups of signal lines in pixel areas electrically coupled to different test circuits including digital-to-analog converter circuits.

FIG. 8 is a diagram for illustrating grouping of signal lines in pixel areas electrically coupled to different test circuits including digital-to-analog converter circuits or resistive divider circuits.

FIG. 9 is an exemplary test pattern generated by test circuits in a circuit chip according to an embodiment of the present technology.

FIGS. 10A to 10C are schematic views depicting exemplary configurations of a pixel chip stacked over a circuit chip according to embodiments of the present technology.

FIG. 11 is a block diagram schematically depicting an outline of a system configuration of a CMOS image sensor which is an example of a solid-state imaging device to which the technology according to the present disclosure is applied.

FIG. 12 is a circuit diagram depicting an exemplary circuit configuration of a pixel circuit.

FIG. 13 is an exploded perspective view schematically depicting a stacked semiconductor chip structure.

FIG. 14 is a block diagram schematically depicting an exemplary configuration of an analog-to-digital conversion section.

FIG. 15 is a schematic circuit diagram of elements of an image sensor array formed on a second (e.g. circuit) chip of a solid-state imaging device with laminated structure according to an embodiment.

FIG. 16 is a diagram depicting an application example of the technology according to the present disclosure.

FIG. 17 is a block diagram depicting an example of a schematic configuration of a vehicle control system.

FIG. 18 is a diagram of assistance in explaining an example of installation positions of an outside-vehicle information detecting section and an imaging section of the vehicle control system of FIG. 17.

### DETAILED DESCRIPTION

Embodiments for implementing techniques of the present disclosure (also referred to as “embodiments” in the following) will be described below in detail using the drawings. The techniques of the present disclosure are not limited to the described embodiments, and various numerical values and the like in the embodiments are illustrative only. The same elements or elements with the same functions are denoted by the same reference signs.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Connected electronic elements may be electrically connected through a direct and/or low-resistive connection, e.g., through a conductive line. The terms “electrically connected” and “electrically coupled” may, in addition to a direct electric connection, also include a connection through other electronic elements provided and suitable for permanent and/or temporary signal transmission and/or transmission of energy. For example, electronic elements may be electrically coupled through resistors, capacitors, and switches such as transistors or transistor circuits, e.g. FETs (field effect transistors), transmission gates, and others. The load path of a transistor is the controlled path of a transistor. For example, a voltage applied to a gate of a FET controls by field effect the current flow through the load path between source and drain.

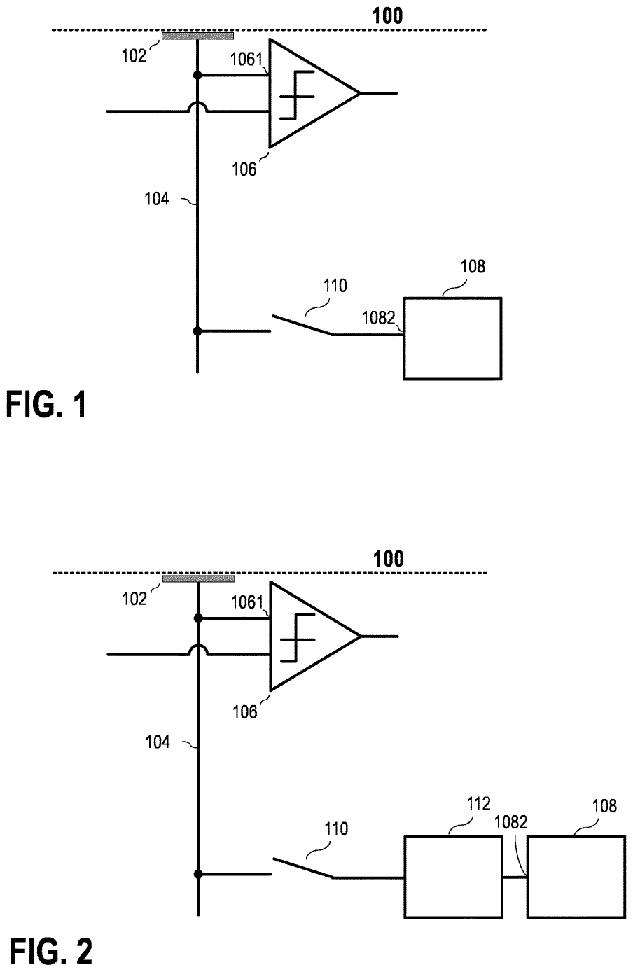

FIG. 1 illustrates a configuration example of a circuit chip 100 according to an embodiment of the present technology. The circuit chip 100 may include a semiconductor substrate, e.g. a silicon semiconductor substrate, and a wiring area over one or both sides of the semiconductor substrate. While circuit elements may be integrated in the semiconductor substrate, the wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The wiring level may allow for electrically connecting circuit elements to one another for realizing functional circuits, e.g. switches, comparators, digital-to-analog converters, analog-to-digital converters, memory elements, charge pumps etc. The wiring level may further allow for providing contact areas configured to be electrically connected from outside of the chip. This may allow for providing the circuit chip with electrical signals from outside of the chip. A contact area may be any area that can be accessed from outside of the chip for providing an electric contact thereto. For example, the contact area may be a pad for wire bonding or flip chip techniques.

The circuit chip 100 may further include a first circuit chip contact area 102. For example, the first circuit chip contact area 102 may be formed as part of the wiring area of the circuit chip 100. The first circuit chip contact area 102 may be a pad that can be electrically connected to a first pixel chip contact area of a pixel chip by comprising stacking the pixel chip over the circuit chip, for example.

The circuit chip 100 may further include a first signal line 104 electrically connected to the first circuit chip contact area 102. For example, the first signal line 104 may be formed as part of the wiring area of the circuit chip 100.

The circuit chip 100 may further include a first comparator circuit 106. The first signal line 104 is electrically coupled, e.g. directly electrically connected, to a first input 1061 of the first comparator circuit 106.

The circuit chip 100 may further include a first test circuit 108. The first test circuit 108 may include a digital-to-analog converter circuit. The first test circuit 108 is configured to output a test signal at an output 1082 of the first test circuit 108.

The circuit chip 100 may further include a first switching element 110. For example, the first switching element 110 may be electrically coupled in series between the output 1082 of the first test circuit 108 and the first signal line 104. For example, the first switching element 110 may be directly electrically connected to the first signal line 104. For example, the first switching element 110 may be or may include an nFET (n channel FET), a pFET (p channel FET) or a transfer gate including FETs of different channel type with the load paths electrically connected in parallel. The switching element 110 may also be a fuse, e.g. a laser fuse. The first switching element 110 may be operable to switch between electrically connecting the output 1082 of the first test circuit 108 and the first signal line 104 and electrically disconnecting the output 1082 of the first test circuit 108 and the first signal line 104 based on a first switching element input signal.

In some examples, the circuit chip 100 may further include a test control circuit configured to generate and output the first switching element input signal to a control input of the first switching element. The test control circuit may be further configured to generate and output a binary test signal to the digital-to-analog converter circuit of the first test circuit.

In some examples, the circuit chip 100 may further include a first test chip contact area electrically coupled to a control input of the first switching element. The circuit chip 100 may further include a second test chip contact area electrically coupled to the digital-to-analog converter circuit of the first test circuit.

In some examples, the circuit chip 100 may further include a voltage ramp generator circuit comprising a second digital-to-analog converter circuit, wherein an output of the voltage ramp generator circuit is electrically connected to a second input of the first comparator circuit.

In some examples of the circuit chip 100, more than 80% of a layout of the second digital-to-analog converter circuit may be reused in the digital-to-analog converter circuit of the first test circuit. This may allow for reducing layout effort and costs.

In some examples of the circuit chip 100, the digital-to-analog converter circuit of the first test circuit is an n-bit digital-to-analog converter circuit, wherein n ranges from 6 to 14. This may allow for a wide variety of test signal levels such as the white and black streaking, and yellow band, etc., thereby improving identification of functional defects of the circuit chip.

In some examples of the circuit chip 100, a layout area of the digital-to-analog converter circuit of the first test circuit may range from 5% to 20%, or from 5% to 30%, or from 5% to 40% of a layout area of the second digital-to-analog converter circuit.

The circuit chip 100 may further include a second circuit chip contact area configured to be electrically connected to a second pixel chip contact area of the pixel chip. The circuit chip 100 may further include a second signal line electrically connected to the second circuit chip contact area. The circuit chip 100 may further include a second comparator circuit. The second signal line may be electrically coupled to a first input of the second comparator circuit. The circuit chip 100 may further include a second test circuit comprising an output. The circuit chip 100 may further include a second switching element electrically coupled in series between the output of the second test circuit and the second signal line. The circuit chip 100 may include a plurality of signal lines. For example, the number of signal lines may be equal to the number of vertical signal lines of a pixel chip that can be stacked on the circuit chip 100 for forming a slid-state imaging device.

In some examples, the circuit chip 100 may include a first number of circuit chip contact areas laterally arranged between the first chip contact area and the second chip contact area, wherein the first number ranges from ⅛ of a total number of the signal lines to the total number of the signal lines. Each of the first number of circuit chip contact areas may be electrically coupled to the first test circuit.

In some examples, the circuit chip 100 may further include a third test circuit comprising a resistive divider circuit. The third test circuit may be configured to output a test signal at an output of the third test circuit. Different test circuits may be connected to different groups of signals lines by a switch array circuit, for example.

An arrangement of the first circuit chip pad 102, the signal line 104, the comparator circuit 106, the switching element 110 may be duplicated in the circuit chip, e.g. depending on a number of vertical signal lines of a pixel chip that may be stacked on the circuit chip.

FIG. 2 illustrates a configuration example of a circuit chip 100 according to another embodiment of the present technology. The circuit chip 100 of FIG. 2 is based on the circuit chip 100 illustrated in FIG. 1 and further includes a switch array circuit 112 electrically coupled in series between the output 1082 of the first test circuit and the first switching element 110. The switch array circuit 112 allows for a specific electric connection between any combination of i) a plurality groups of signal lines and ii) a plurality of test circuits. For example, a first group of adjacent signal lines may be electrically coupled to the first test circuit and a second group of adjacent signal lines may be electrically coupled to a second test circuit. This mapping may be set by the switching array circuit 112.

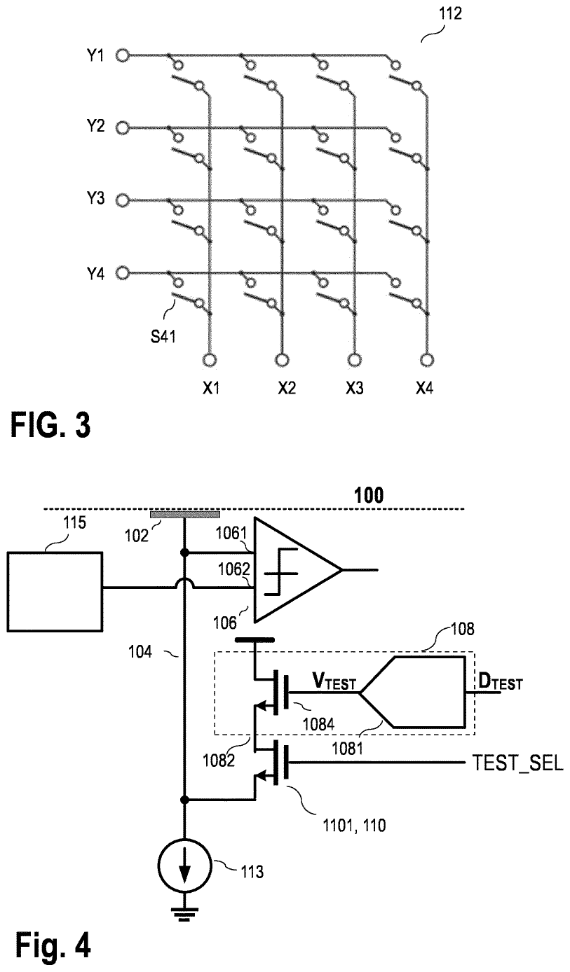

FIG. 3 illustrates an exemplary circuit configuration of a switching array circuit 112 that is based on a crosspoint matrix switch. For example, each of nodes Y1 to Y4 may be electrically connected to a first, second, third and fourth group of signal lines, respectively. Likewise, each of nodes X1 to X4 may be electrically connected to a first, second, third or fourth test circuit, respectively. The number of nodes X may vary and is not limited to the illustrated number 4. Likewise, the number of nodes Y may vary and is not limited to the illustrated number 4. At each of the crosspoints of the matrix switch, a switching element is located for electrically connecting or disconnecting the nodes X any Y that are associated with the respective crosspoint. For example, a switching element S41, e.g. a transistor switching element, provides an electrical connection or disconnection between nodes Y4 and X1.

FIG. 4 illustrates an exemplary circuit configuration of the circuit chip 100 that is based on the example of FIG. 1. The first test circuit 108 may include a digital-to-analog converter circuit 1081. The first test circuit 108 is configured to output a test signal at an output 1082 of the first test circuit 108. The circuit chip 100 may further include an nFET 1101, i.e. n-channel FET (n-channel field effect transistor) as the first switching element 110. The digital-to-analog converter circuit 1081 is configured to receive a binary input test signal D_{TEST} and output an analog test signal V_{TEST}. The analog test signal V_{TEST} is supplied to the first signal line 104 via an nFET 1084 of the first test circuit 108 and the nFET 1101 of the first switching element 110. The first switching element 110 is operable to switch between electrically connecting the output 1082 of the first test circuit 108 and the first signal line 104 and electrically disconnecting the output 1082 of the first test circuit 108 and the first signal line 104 based on a first switching element input signal TEST_SEL supplied to a control input 1102, e.g. gate of the switching element 110. An output of a voltage ramp generator circuit 115 comprising a second digital-to-analog converter circuit may be electrically connected to a second input 1062 of the first comparator circuit 106. The first signal line 104 may be electrically coupled to GND via a current source circuit 113.

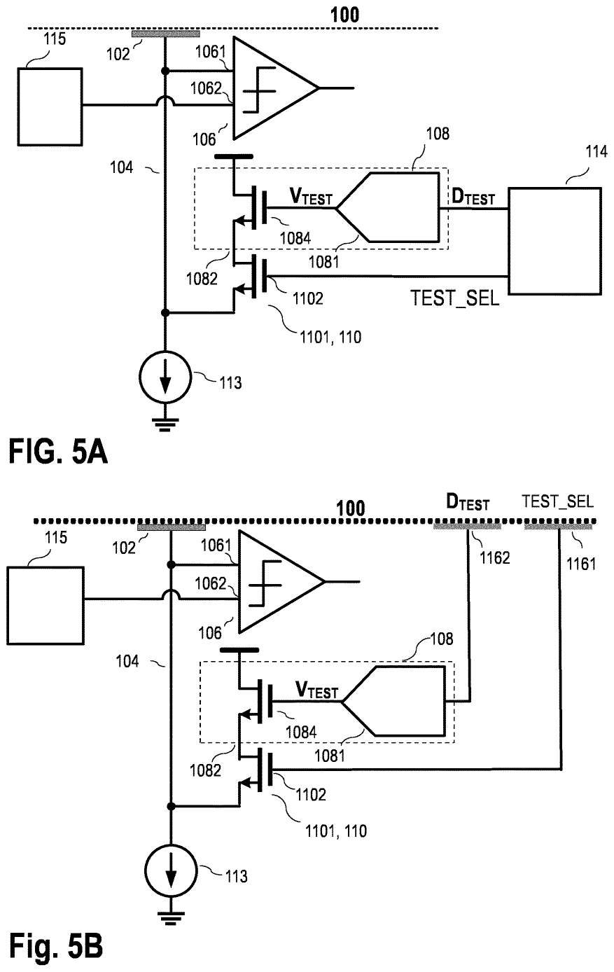

FIG. 5A illustrates an exemplary circuit configuration of the circuit chip 100 that is based on the example of FIG. 4. The circuit chip 100 further includes a test control circuit 114 configured to generate and output the first switching element input signal TEST_SEL to a control input 1102 of the first switching element 110, i.e. gate of the nFET 1101. The test control circuit 114 is further configured to generate and output the binary test signal D_{TEST} to the digital-to-analog converter circuit 1081 of the first test circuit 108.

FIG. 5B illustrates another exemplary circuit configuration of the circuit chip 100 that is based on the example of FIG. 4. The circuit chip 100 further includes a first test chip contact area 1161 electrically coupled to the control input 1102 of the first switching element 110, i.e. gate of the nFET 1101. The circuit chip 100 further includes a second test chip contact area 1162 electrically coupled to the digital-to-analog converter circuit 1081 of the first test circuit 108. This configuration may allow for generating the test signals D_{TEST} and TEST_SEL outside of the circuit chip 100, e.g. by a tester equipment.

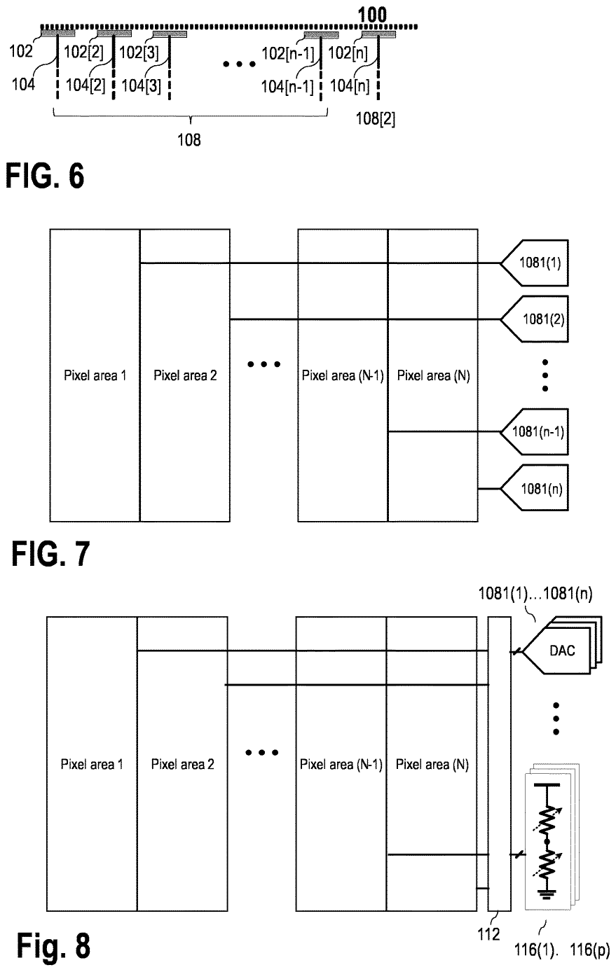

FIG. 6 is a simplified diagram depicting an exemplary interconnecting scheme of circuit pads and test circuits. The circuit chip 100 includes a second circuit chip contact area 102[n]. A second signal line 104[n] is electrically connected to the second circuit chip contact area 102[n]. Similar to the arrangement illustrated in FIG. 1 but not depicted in FIG. 6 to simplify matters, the circuit chip 100 further includes a second comparator circuit, wherein the second signal line 102[n] is electrically coupled to a first input of the second comparator circuit, and a second switching element electrically coupled in series between an output of a second test circuit 108[2] and the second signal line 104[n]. A first number, e.g. n−2 in FIG. 6, of circuit chip contact areas is laterally arranged between the first chip contact area 102 and the second chip contact area 102[n]. For example, the first number may range from ⅛ of a total number of the signal lines (e.g. the number of signal lines electrically connected to a comparator circuit for testing) to the total number of the signal lines. Each of the first number of circuit chip contact areas, i.e. chip contact areas 102[2] . . . 102[n−1], are electrically coupled to the first test circuit 108 via the first switching element 110.

FIG. 7 illustrates an exemplary circuit configuration of the circuit chip 100. Each of the pixel areas 1 to N includes a group of signal lines in the circuit chip 100. The signal lines of each group may be adjacent to one another, for example. For example, a group of signal lines, e.g. including the first signal line 104 illustrated in the examples above, associated with the pixel area 1 may include adjacent signal lines at a first side of the circuit chip 104, and a group of signal lines associated with the pixel area N may include adjacent signal lines at a second side (opposite to the first side) of the circuit chip. Each signal line of a specific group is electrically coupled to a specific one of the digital-to-analog converter circuits 1081(1) . . . 1081(n). In other words, signal lines of different groups or pixel areas 1 . . . (N) are electrically coupled to different test circuits.

FIG. 8 illustrates another exemplary circuit configuration of the circuit chip 100. In addition to using different digital-to-analog converter circuits 1081(1) . . . 1081(n) for different groups of signal lines as illustrated in FIG. 7, the circuit chip 100 may further include one or more resistive divider circuits 116(1) . . . 116(p). The signal lines of each group or pixel area may be electrically coupled to one of the digital-to-analog converter circuits 1081(1) . . . 1081(n) or to one of the resistive divider circuits 116(1) . . . 116(p). The mapping of the pixel areas to the test circuits, i.e. the test circuits including either one of the digital-to-analog converter circuits (DACs) 1081(1) . . . 1081(n) or one of the resistive divider circuits 116(1) . . . 116(p), is carried out by the switch array circuit 112.

The circuit chip 100 including one or more test circuits including a digital to analog-converter circuit, and, optionally in addition, one or more resistive divider circuits, allows for flexible patterns for wafer testing. This may allow for simplifying identification of functional defects by wafer testing of circuit chips, for example.

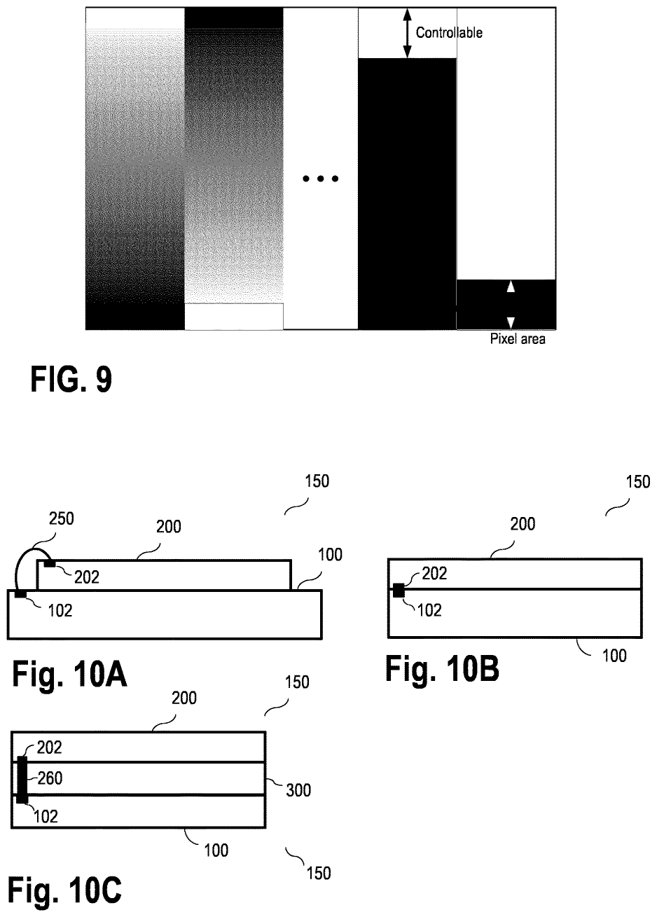

Flexible patterns for wafer testing enabled by the circuit chips described herein are illustrated in the exemplary pattern of FIG. 9 including pixel area patterns that may be defined by test circuits comprising a digital-to-analog converter circuit (e.g. left side pixel areas in FIG. 9) and pixel area patterns that may be defined by test circuits comprising resistive divider circuits circuit (e.g. right side pixel areas in FIG. 9). The patterns may be generated by test image generation row-by-row, wherein for each row of the test image, the test signals are supplied to the signal lines via the test circuits.

FIGS. 10A to 10C illustrate exemplary configurations of solid-state imaging devices 150. The solid-state imaging devices 150 include the circuit chip 100 as described in any of the examples herein. A pixel chip 200 is stacked over the circuit chip 100. The pixel chip 200 includes a plurality of pixel circuits. A group of the plurality of pixel circuits is electrically coupled to a vertical signal that is electrically connected to the first signal line of the circuit chip 100 via a first pixel chip contact area 202 and the first circuit chip contact area 102. Exemplary configurations of interconnecting the first pixel chip contact area 202 and the first circuit chip contact area 102 are illustrated in FIGS. 10A to 10C. A bond wire 250 may be used for the connection (see FIG. 10A). A flip chip technique may be used (see FIG. 10B). As is illustrated in FIG. 10C, the flip chip technique may be combined with an intermediate third chip 300. A TSV (through silicon via) or TCV (through chip via) 260 may provide an electric connection through the third chip 300. TSVs or TCVs involve actually creating a separate pathway through the “stack” by chemically etching, or using lasers or other techniques. The chips may be adhered to each other, e.g. by a film adhesive. The interconnection techniques may be combined and the number of stacked chips may be varied and adapted to the specific needs as required.

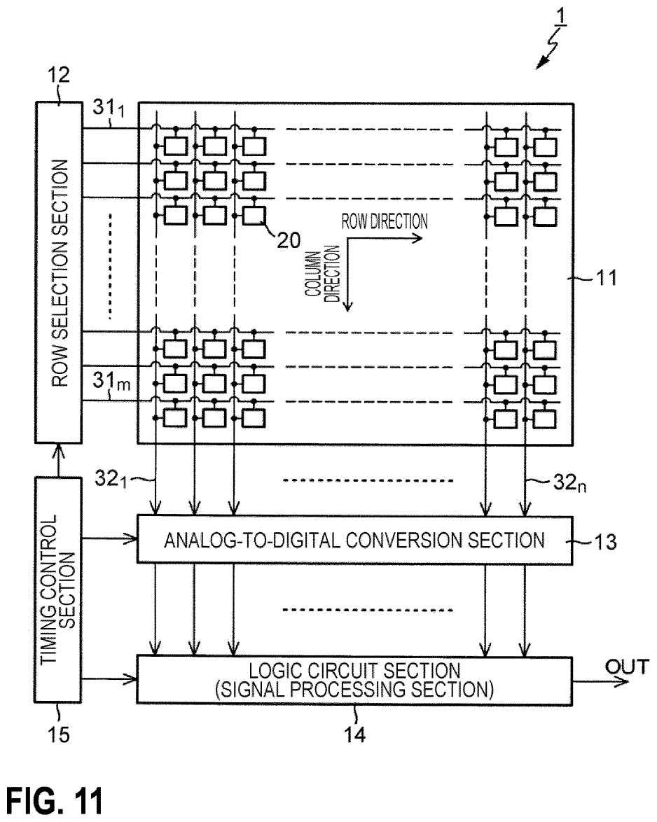

FIG. 11 is a block diagram schematically depicting an outline of a system configuration of the CMOS image sensor which is an example of the solid-state imaging device 150 to which the technology according to the present disclosure is applied.

A CMOS image sensor 1 may include a pixel array section 11 and a peripheral circuit section of the pixel array section 11. The pixel array section 11 has a configuration in which pixels (pixel circuits) 20 including light receiving elements are two-dimensionally arranged in a row direction and a column direction, that is, in a matrix. Here, the row direction refers to an array direction of the pixels 20 in a pixel row, and the column direction refers to an array direction of the pixels 20 in a pixel column. The pixel 20 performs photoelectric conversion to generate and accumulate a photocharge corresponding to the amount of received light.

The peripheral circuit section of the pixel array section 11 includes, for example, a row selection section 12, an analog-to-digital conversion section 13, a logic circuit section 14 as a signal processing section, a timing control section 15, and the like.

In the pixel array section 11, pixel control lines 31 (31₁ to 31ₘ) are wired along the row direction for each pixel row with respect to the matrix-shaped pixel array. Furthermore, vertical signal lines 32 (32₁ to 32ₙ) are wired along the column direction for each pixel column. The pixel control line 31 transmits a drive signal for performing driving at the time of reading a signal from the pixel 20. The pixel control line 31 is illustrated as one wiring in FIG. 1, but is not limited to one. The pixel control line 31 has one end connected to an output end corresponding to each row of the row selection section 12.

Hereinafter, the respective constituent elements of the peripheral circuit section of the pixel array section 11, that is, the row selection section 12, the analog-to-digital conversion section 13, the logic circuit section 14, and the timing control section 15 will be described.

The row selection section 12 includes a shift register, an address decoder, and the like, and controls scanning of pixel rows and addresses of pixel rows in selection of each of the pixels 20 of the pixel array section 11. The row selection section 12 generally includes two scanning systems of a reading scanning system and a sweeping scanning system although a specific configuration thereof is not illustrated.

The reading scanning system sequentially selects and scans the pixels 20 of the pixel array section 11 row by row in order to read a pixel signal from the pixel 20. The pixel signal read from the pixel 20 is an analog signal. The sweeping scanning system performs sweeping scanning on a reading row on which reading scanning is to be performed by the reading scanning system prior to the reading scanning by a time corresponding to a shutter speed.

The sweeping scanning performed by the sweeping scanning system sweeps out unnecessary charges from photoelectric conversion elements of the pixels 20 in the reading row, whereby the photoelectric conversion elements are reset. Then, a so-called electronic shutter operation is performed by sweeping out (resetting) the unnecessary charges by the sweeping scanning system. Here, the electronic shutter operation refers to an operation of sweeping out photocharges of photoelectric conversion elements and newly starting exposure (starting accumulation of photocharges).

The analog-to-digital conversion section 13 includes a set of a plurality of analog-to-digital converters (ADC) provided to correspond to the pixel columns (for example, for each pixel column) of the pixel array section 11. The analog-to-digital conversion section 13 is a column-parallel analog-to-digital conversion section that converts an analog pixel signal output through each of the signal lines 32₁ to 32ₙ into a digital signal for each pixel column. For example, the analog-to-digital conversion section 13 is an exemplary circuit configuration that may be included in the circuit chip 100 of the examples described above and below.

As the analog-to-digital converter in the analog-to-digital conversion section 13, it is possible to use, for example, a single-slope analog-to-digital converter, which is an example of a reference signal comparison analog-to-digital converter.

The logic circuit section 14, which is the signal processing section, reads the pixel signal digitized by the analog-to-digital conversion section 13 and performs predetermined signal processing. Specifically, as the predetermined signal processing, the logic circuit section 14 performs, for example, correction of a vertical line defect and a point defect or clamping of a signal, and further, digital signal processing such as parallel-to-serial conversion, compression, encoding, addition, averaging, or intermittent operation. The logic circuit section 14 outputs generated image data to a subsequent device as an output signal OUT of the CMOS image sensor 1.

The timing control section 15 generates various timing signals, clock signals, control signals, and the like on the basis of a synchronization signal provided from the outside. Then, the timing control section 15 controls driving of the row selection section 12, the analog-to-digital conversion section 13, the logic circuit section 14, and the like on the basis of the generated signals.

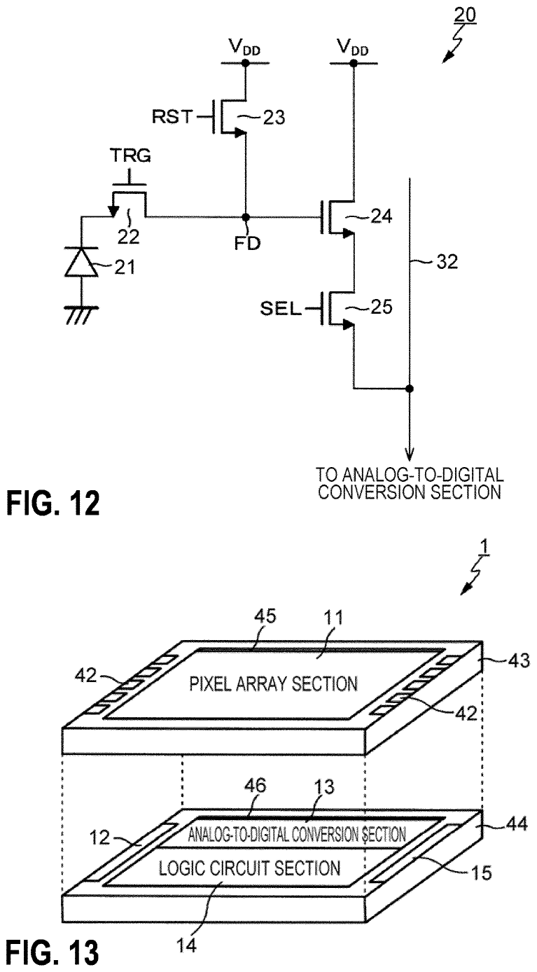

FIG. 12 is a circuit diagram depicting an exemplary circuit configuration of the pixel or pixel circuit 20. The pixel 20 includes, for example, a photodiode 21 as the photoelectric conversion element. The pixel 20 includes a transfer transistor 22, a reset transistor 23, an amplification transistor 24, and a selection transistor 25 in addition to the photodiode 21. Other pixel circuit designs that may be based on a different number of transistors per pixel circuit may likewise be used.

As the four transistors of the transfer transistor 22, the reset transistor 23, the amplification transistor 24, and the selection transistor 25, for example, N-channel MOS field-effect transistors are used. However, a combination of conductivity types of the four transistors 22 to 25 exemplified here is merely an example, and the combination is not limited thereto.

For the pixel 20, as the above-described pixel control lines 31 (31₁ to 31ₘ), a plurality of pixel control lines is wired in common to the respective pixels 20 in the same pixel row. The plurality of pixel control lines is connected to an output end corresponding to each pixel row of the row selection section 12 in units of pixel rows. The row selection section 12 appropriately outputs a transfer signal TRG, a reset signal RST, and a selection signal SEL to the plurality of pixel control lines.

The photodiode 21 has an anode electrode connected to a low-potential-side power supply (for example, ground), photoelectrically converts received light into photocharges (here, photoelectrons) of a charge amount corresponding to the amount of the light, and accumulates the photocharges. The photodiode 21 has a cathode electrode electrically connected to a gate electrode of the amplification transistor 24 via the transfer transistor 22. Here, a region where the gate electrode of the amplification transistor 24 is electrically connected is a floating diffusion (floating diffusion region/impurity diffusion region) FD. The floating diffusion FD is a charge-voltage conversion section that converts a charge into a voltage.

The transfer signal TRG activated at a high level (for example, V_{DD} level) is supplied from the row selection section 12 to a gate electrode of the transfer transistor 22. The transfer transistor 22 is brought into a conductive state in response to the transfer signal TRG, thereby transferring the photocharges, photoelectrically converted by the photodiode 21 and accumulated in the photodiode 21, to the floating diffusion FD.

The reset transistor 23 is connected between a node of a high-potential-side power supply voltage V_{DD} and the floating diffusion FD. The reset signal RST that is activated at a high level is provided from the row selection section 12 to a gate electrode of the reset transistor 23. The reset transistor 23 is brought into a conductive state in response to the reset signal RST, and resets the floating diffusion FD by sweeping out charges of the floating diffusion FD to the node of the voltage V_{DD}.

The amplification transistor 24 has the gate electrode connected to the floating diffusion FD and a drain electrode connected to the node of the high-potential-side power supply voltage V_{DD}. The amplification transistor 24 serves as an input section of a source-follower that reads a signal obtained by photoelectric conversion in the photodiode 21. That is, the amplification transistor 24 has a source electrode connected to the signal line 32 via the selection transistor 25.

The selection transistor 25 has a drain electrode connected to the source electrode of the amplification transistor 24 and a source electrode connected to the signal line 32. The selection signal SEL that is activated at a high level is provided from the row selection section 12 to a gate electrode of the selection transistor 25. The selection transistor 25 is brought into a conductive state in response to the selection signal SEL, thereby transmitting the signal output from the amplification transistor 24 to the signal line 32 with the pixel 20 in a selected state.

Note that the pixel 20 adopting a 4-Tr configuration including four transistors, that is, the transfer transistor 22, the reset transistor 23, the amplification transistor 24, and the selection transistor 25 has been exemplified in the above-described circuit example, but the present invention is not limited thereto. For example, a 3-Tr configuration in which the selection transistor 25 is omitted and the amplification transistor 24 also functions as the selection transistor 25 can also be adopted, and a 5-Tr or more configuration in which the number of transistors is increased can also be adopted as necessary.

As a semiconductor chip structure of the CMOS image sensor 1 having the above-described configuration, a a stacked semiconductor chip structure can be exemplified. Furthermore, regarding a pixel structure, assuming that a substrate surface on a side on which a wiring area is formed is defined as a front surface (front), it is possible to adopt a back surface irradiation pixel structure which captures light irradiated from a back surface side on the opposite side, or a front surface irradiation pixel structure which captures light irradiated from the front surface side.

Hereinafter, an outline of the stacked semiconductor chip structure will be described.

FIG. 13 is an exploded perspective view schematically depicting the stacked semiconductor chip structure of the CMOS image sensor 1. As depicted in FIG. 13, the stacked semiconductor chip structure, that is, the stacked structure has a structure in which at least two semiconductor chips of a semiconductor chip 43 of the first layer and a semiconductor chip 44 of the second layer are stacked.

In this stacked semiconductor chip structure, the semiconductor chip 43 of the first layer is a pixel chip in which the pixel array section 11 in which the pixels 20 including photoelectric conversion elements (for example, the photodiodes 21) are two-dimensionally arranged in a matrix is formed. The pads 42 for external connection and power supply are provided, for example, at both left and right ends of the semiconductor chip 43 of the first layer.

The semiconductor chip 44 of the second layer is a circuit chip in which the peripheral circuit section of the pixel array section 11, that is, the row selection section 12, the analog-to-digital conversion section 13, the logic circuit section 14, the timing control section 15, and the like are formed. Note that the arrangement of the row selection section 12, the analog-to-digital conversion section 13, the logic circuit section 14, and the timing control section 15 is an example, and is not limited to this arrangement example.

The pixel array section 11 on the semiconductor chip 43 of the first layer and the peripheral circuit section on the semiconductor chip 44 of the second layer are electrically connected via junction portions 72 and 73 including a metal-metal junction including a Cu—Cu junction, a through silicon via (TSV), a micro-bump, and the like.

According to the stacked semiconductor chip structure described above, a process suitable for manufacturing the pixel array section 11 can be applied to the semiconductor chip 43 of the first layer, and a process suitable for manufacturing the circuit part can be applied to the semiconductor chip 44 of the second layer. Therefore, the processes can be optimized in manufacturing the CMOS image sensor 1. Therefore, the processes can be optimized in manufacturing the CMOS image sensor 1. In particular, an advanced process can be applied to manufacture the circuit part.

Next, an exemplary configuration of the analog-to-digital conversion section 13 will be described. Here, a single-slope analog-to-digital converter is used as each analog-to-digital converter of the analog-to-digital conversion section 13.

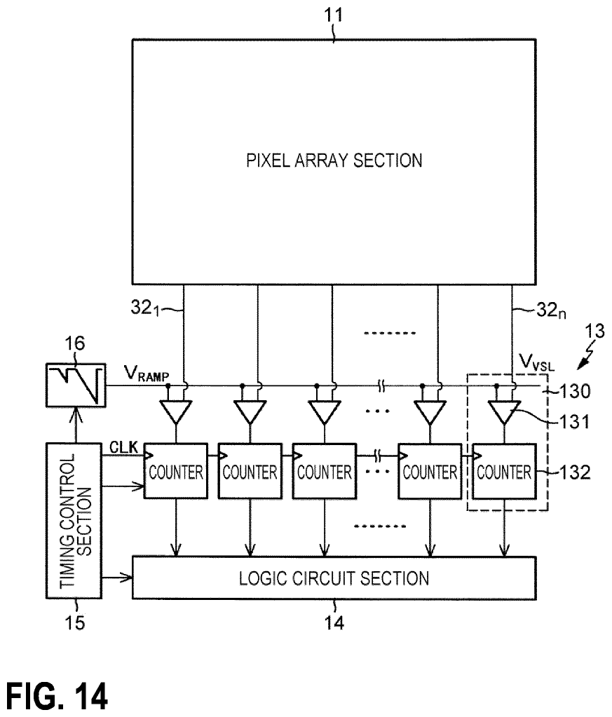

FIG. 14 illustrates the exemplary configuration of the analog-to-digital conversion section 13. In the CMOS image sensor 1, the analog-to-digital conversion section 13 includes a set of a plurality of single-slope analog-to-digital converters provided to respectively correspond to pixel columns of the pixel array section 11. Here, a single-slope analog-to-digital converter 130 of the n-th column will be described as an example.

The analog-to-digital converter 130 has a circuit configuration including a comparator 131 and a counter 132. Then, in the single-slope analog-to-digital converter 130, a reference signal generated by a reference signal generating section 16 is used. The reference signal generating section 16 includes, for example, a digital-to-analog converter (DAC), generates a reference signal V_{RAMP} of a sloped waveform (so-called ramp wave) whose level (voltage) monotonously decreases with the passage of time, and provides the reference signal V_{RAMP} to the comparator 131 provided for each pixel column as a standard signal.

The comparator 131 uses an analog pixel signal V_{VSL} read from the pixel 20 as a comparison input and the reference signal V_{RAMP} of the ramp wave generated by the reference signal generating section 16 as a reference input to compares both the signals. Then, for example, an output of the comparator 131 is in a first state (high level) when the reference signal V_{RAMP} is more than the pixel signal V_{VSL}, and an output is in a second state (for example, low level) when the reference signal V_{RAMP} is equal to or less than the pixel signal V_{VSL}. Therefore, the comparator 131 outputs, as a comparison result, a pulse signal having a pulse width according to a signal level of the pixel signal V_{VSL}, specifically, corresponding to the magnitude of the signal level.

A clock signal CLK is supplied from the timing control section 15 to the counter 132 at the same timing as a supply start timing of the reference signal V_{RAMP} to the comparator 131. Then, the counter 132 performs a counting operation in synchronization with the clock signal CLK to measure a period of a pulse width of an output pulse of the comparator 131, that is, a period from the start of a comparison operation to the end of the comparison operation. A count result (count value) of the counter 132 is supplied to the logic circuit section 14 as a digital value obtained by digitizing the analog pixel signal V_{VSL}.

According to the analog-to-digital conversion section 13 including the set of single-slope analog-to-digital converters 130 described above, it is possible to obtain a digital value from time information until a magnitude relationship between the reference signal V_{RAMP} of the ramp wave generated by the reference signal generating section 16 and the analog pixel signal V_{VSL} read from the pixel 20 through the signal line 32 changes.

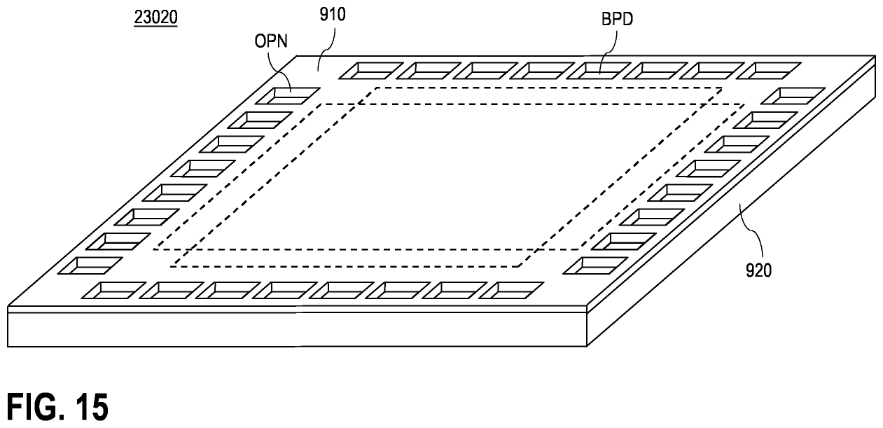

FIG. 15 is a perspective view showing an example of a laminated structure of a solid-state imaging device 23020 with a plurality of pixels arranged matrix-like in array form. Each pixel includes at least one photoelectric conversion element.

The solid-state imaging device 23020 has the laminated structure of a first chip (upper chip) 910 and a second chip (lower chip) 920. The first chip (upper chip) 910 is one example for the pixel chip described and illustrated with respect to examples above. The second chip (lower chip) 920 is one example for the circuit chip described and illustrated with respect to examples above. The laminated first and second chips 910, 920 may be electrically connected to each other through TC(S)Vs (Through Contact (Silicon) Vias) formed in the first chip 910. The solid-state imaging device 23020 may be formed to have the laminated structure in such a manner that the first and second chips 910 and 920 are bonded together at wafer level and cut out by dicing.

In the laminated structure of the upper and lower two chips, the first chip 910 may be an analog chip (sensor chip) including at least one analog component of each pixel circuit, e.g., the photoelectric conversion elements arranged in array form.

For example, the first chip 910 may include only the photoelectric conversion elements of the pixel circuits as described above with reference to the preceding FIGS. Alternatively, the first chip 910 may include further elements of each pixel circuit. For example, the first chip 910 may include, in addition to the photoelectric conversion elements, at least the transfer transistor, the reset transistor, the amplifier transistor, and/or the selection transistor of the pixel circuits. Alternatively, the first chip 910 may include each element of the pixel circuit.

The second chip 920 may be mainly a logic chip (digital chip) that includes the elements complementing the elements on the first chip 910 to complete pixel circuits and current control circuits. The second chip 920 may also include analog circuits, for example circuits that quantize analog signals transferred from the first chip 910 through the TCVs. For example, the second chip 920 may include all or at least some of the components of the row driver assembly.

The second chip 920 may have one or more bonding pads BPD and the first chip 910 may have openings OPN for use in wire-bonding to the second chip 920. The solid-state imaging device 23020 with the laminated structure of the two chips 910, 920 may have the following characteristic configuration:

The electrical connection between the first chip 910 and the second chip 920 is performed through, for example, the TCVs. The TCVs may be arranged at chip ends or between a pad region and a circuit region. The TCVs for transmitting control signals and supplying power may be mainly concentrated at, for example, the four corners of the solid-state imaging device 23020, by which a signal wiring area of the first chip 910 can be reduced.

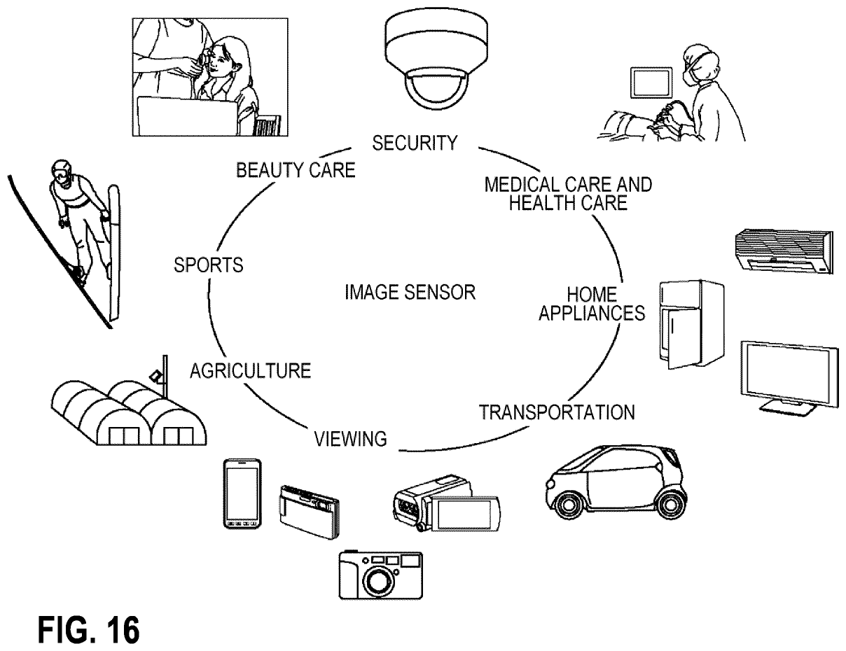

Examples of Application will be described below. The solid-state imaging device according to the examples described above can be used for various devices that sense light such as visible light, infrared light, ultraviolet light, and X-rays, for example, as depicted in FIG. 16. Specific examples of the various devices are listed hereinafter:
i) A device that captures an image for use in viewing, such as a digital camera or a portable device equipped with a camera function.
ii) A device used in transportation, such as a vehicle-mounted sensor that captures images of a front, a rear, surroundings, an interior, and the like of a vehicle, a monitoring camera that monitors traveling vehicles and roads, or a range-finding sensor that measures a distance between vehicles and the like, for safety driving such as automatic stop, recognition of a state of a driver state, and the like
iii) A device used for home appliances such as a TV, a refrigerator, and an air conditioner, to capture an image of a gesture of a user and operate such an appliance in accordance with the gesture.
iv) A device used for medical care and health care, such as an endoscope or a device that performs angiography by receiving infrared light.
v) A device used for security, such as a monitoring camera for a crime prevention application or a camera for a person authentication application.
vi) A device used for beauty care, such as a skin measuring instrument that captures an image of a skin or a microscope that captures an image of a scalp.
vi) A device used for sports, such as an action camera or a wearable camera for sports applications and the like
vii) A device used for agriculture, such as a camera for monitoring states of fields and crops.

The technology according to the present disclosure may be realized in a light receiving device mounted in a mobile body of any type such as automobile, electric vehicle, hybrid electric vehicle, motorcycle, bicycle, personal mobility, airplane, drone, ship, or robot.

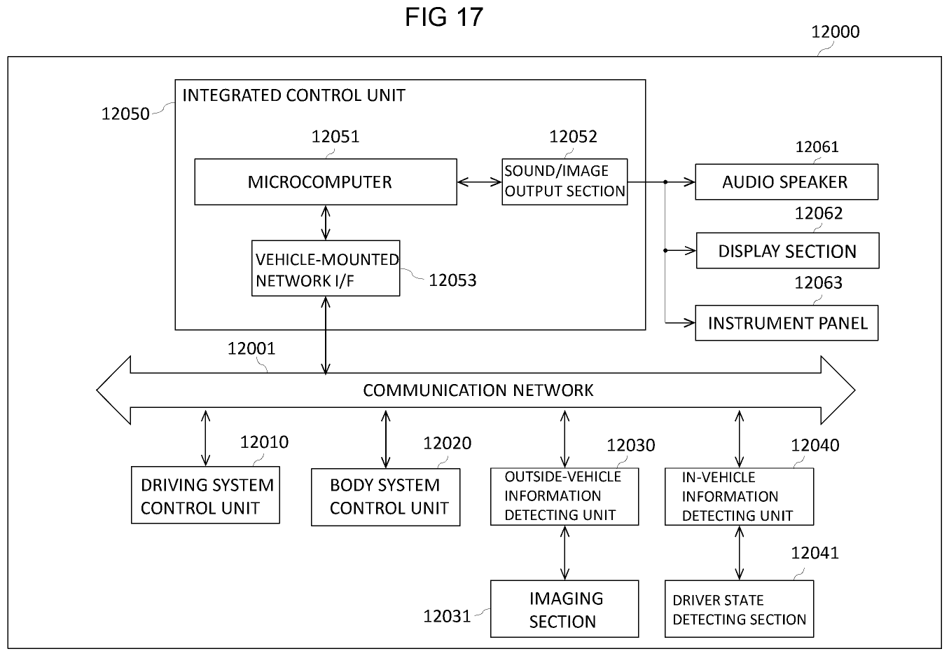

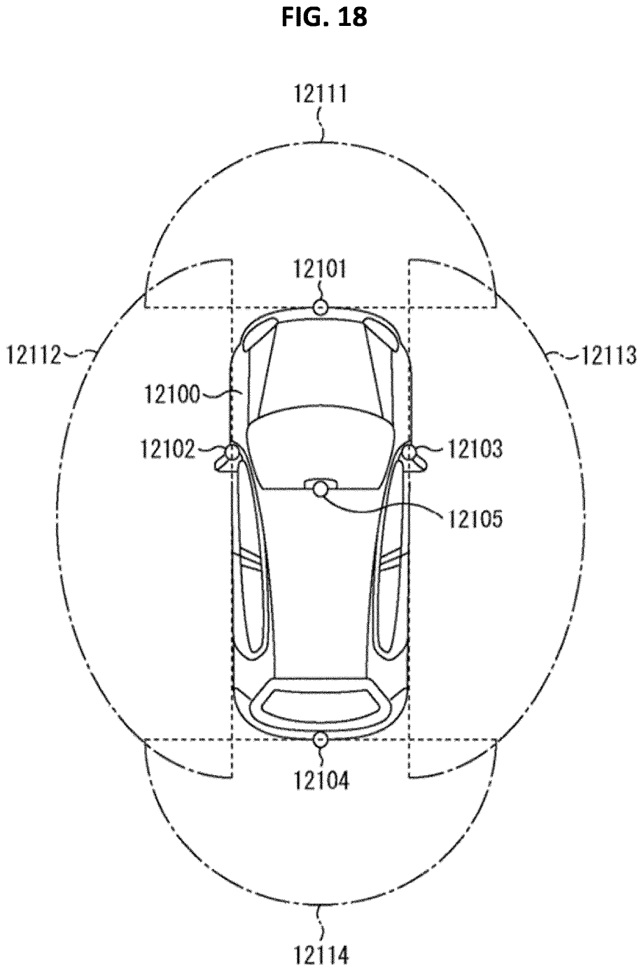

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 imaging an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 may be or may include an image sensor that includes an ADC with a voltage ramp generator according to the embodiments of the present disclosure. The light received by the imaging section 12031 may be visible light, or may be invisible light such as infrared rays or the like.

The in-vehicle information detecting unit 12040 detects information about the inside of the vehicle and may be or may include a solid-state imaging device with a raw driver assembly according to the embodiments of the present disclosure. The in-vehicle information detecting unit 12040 is, for example, connected with a driver state detecting section 12041 that detects the state of a driver. The driver state detecting section 12041, for example, includes a camera that includes the solid-state imaging device and that is focused on the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or audible notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display or a head-up display, wherein each of them may include a solid-state imaging device using a latch comparator circuit for event detection.

FIG. 18 is a diagram depicting an example of the installation position of the imaging section 12031, wherein the imaging section 12031 may include imaging sections 12101, 12102, 12103, 12104, and 12105.

The imaging sections 12101, 12102, 12103, 12104, and 12105 are, for example, disposed at positions on a front nose, side-view mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the side view mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the side view mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, imaging element having pixels for phase difference detection or may include a ToF module including a high dynamic range image sensor that includes an ADC with a voltage ramp generator according to the present disclosure.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control Intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to an embodiment of the present disclosure is applicable has been described above. By applying an image sensor that includes an ADC with a voltage ramp generator according to the present disclosure, the results of image recognition can be more reliable. For example, recognition of pedestrians can be performed on more reliable pixel information. A faulty image sensor can be reliably detected and reported to a higher instance.

Additionally, embodiments of the present technology are not limited to the above-described embodiments, but various changes can be made within the scope of the present technology without departing from the gist of the present technology.

A solid-state imaging device including an image sensor that includes an ADC with a voltage ramp generator circuit according to the present disclosure may be any device used for analyzing and/or processing radiation such as visible light, infrared light, ultraviolet light, and X-rays. For example, the solid-state imaging device may be any electronic device in the field of traffic, the field of home appliances, the field of medical and healthcare, the field of security, the field of beauty, the field of sports, the field of agriculture, the field of image reproduction or the like.

Specifically, in the field of image reproduction, the solid-state imaging device may be a device for capturing an image to be provided for appreciation, such as a digital camera, a smart phone, or a mobile phone device having a camera function. In the field of traffic, for example, the solid-state imaging device may be integrated in an in-vehicle sensor that captures the front, rear, peripheries, an interior of the vehicle, etc. for safe driving such as automatic stop, recognition of a state of a driver, or the like, in a monitoring camera that monitors traveling vehicles and roads, or in a distance measuring sensor that measures a distance between vehicles or the like.

In the field of home appliances, the solid-state imaging device may be integrated in any type of sensor that can be used in devices provided for home appliances such as TV receivers, refrigerators, and air conditioners to capture gestures of users and perform device operations according to the gestures. Accordingly the solid-state imaging device may be integrated in home appliances such as TV receivers, refrigerators, and air conditioners and/or in devices controlling the home appliances. Furthermore, in the field of medical and healthcare, the solid-state imaging device may be integrated in any type of sensor, e.g. a solid-state image device, provided for use in medical and healthcare, such as an endoscope or a device that performs angiography by receiving infrared light.

In the field of security, the solid-state imaging device can be integrated in a device provided for use in security, such as a monitoring camera for crime prevention or a camera for person authentication use. Furthermore, in the field of beauty, the solid-state imaging device can be used in a device provided for use in beauty, such as a skin measuring instrument that captures skin or a microscope that captures a probe. In the field of sports, the solid-state imaging device can be integrated in a device provided for use in sports, such as an action camera or a wearable camera for sport use or the like. Furthermore, in the field of agriculture, the solid-state imaging device can be used in a device provided for use in agriculture, such as a camera for monitoring the condition of fields and crops.

The present technology can also be configured as described below:
[1] A circuit chip (100), comprising:
   a first circuit chip contact area (102) configured to be electrically connected to a first pixel chip contact area (201) of a pixel chip (200);
   a first signal line (104) electrically connected to the first circuit chip contact area (102);
   a first comparator circuit (106), wherein the first signal line (104) is electrically coupled to a first input (1061) of the first comparator circuit (106);
   a first test circuit (108) comprising a digital-to-analog converter circuit (1081), the first test circuit (108) being configured to output a test signal at an output (1082) of the first test circuit (108); and
   a first switching element (110) electrically coupled in series between the output (1082) of the first test circuit and the first signal line.
[2] The circuit chip of [1] described above, wherein the first switching element (110) is operable to switch between electrically connecting the output (1082) of the first test circuit (108) and the first signal line (104) and electrically disconnecting the output (1082) of the first test circuit (108) and the first signal line (104) based on a first switching element input signal (TEST_SEL).
[3]. The circuit chip of [1] or [2] described above, further comprising a test control circuit (114) configured to generate and output the first switching element input signal (TEST_SEL) to a control input (1102) of the first switching element (110), and wherein the test control circuit (114) is further configured to generate and output a binary test signal (D_{TEST}) to the digital-to-analog converter circuit (1081) of the first test circuit (108).
[4] The circuit chip of any of [1] to [2] described above, further comprising a first test chip contact area (1161) electrically coupled to a control input (1102) of the first switching element (110), and a second test chip contact area (1162) electrically coupled to the digital-to-analog converter circuit (108) of the first test circuit (108).
[5] The circuit chip of any of [1] to [4] described above, further comprising:
   a voltage ramp generator circuit (115) comprising a second digital-to-analog converter circuit, wherein an output of the voltage ramp generator circuit (115) is electrically connected to a second input (1062) of the first comparator circuit (106).
[6] The circuit chip of [5] described above, wherein more than 80% of a layout of the second digital-to-analog converter circuit is reused in the digital-to-analog converter circuit (1081) of the first test circuit (108).
[7] The circuit chip of [5] described above, wherein the digital-to-analog converter circuit (1081) of the first test circuit (108) is an n-bit digital-to-analog converter circuit, n ranging from 6 to 14.
[8] The circuit chip of [7] described above, wherein a layout area of the digital-to-analog converter circuit (1081) of the first circuit (108) ranges from 5% to 20% of a layout area of the second digital-to-analog converter circuit.
[9] The circuit chip of any of [1] to [8] described above, further comprising:
   a second circuit chip contact area (102[n]) configured to be electrically connected to a second pixel chip contact area of the pixel chip;
   a second signal line (104[n]) electrically connected to the second circuit chip contact area (102[n]);
   a second comparator circuit, wherein the second signal line (104[n]) is electrically coupled to a first input of the second comparator circuit;
   a second test circuit (108[2]) comprising an output; and
   a second switching element electrically coupled in series between the output of the second test circuit (108[2]) and the second signal line (104[n]).
[10] The circuit chip of [9] described above, further comprising
   a first number of circuit chip contact areas laterally arranged between the first chip contact area (102) and the second chip contact area (102[n]), wherein the first number ranges from ⅛ of a total number of the signal lines to the total number of the signal lines, wherein each of the first number of circuit chip contact areas is electrically coupled to the first switching element (110).
[11] The circuit chip of any of [1] to [10] described above, further comprising
   a third test circuit comprising a resistive divider circuit (116(1)), the third test circuit being configured to output a test signal at an output of the third test circuit.
[12] The circuit chip of [11] described above, further comprising
   a switch array circuit (112) electrically coupled in series between the output of the third test circuit and the first switching element (110).
[13] A solid-state imaging device, comprising:
   the circuit chip of any of [1] to [12] as described above; and
   the pixel chip (200) stacked over the circuit chip (100), wherein the pixel chip includes a plurality of pixel circuits arranged in a matrix pattern, and a first vertical signal line, wherein a group of the plurality of pixel circuits is electrically coupled to the first vertical signal line, and the first vertical signal is electrically connected to the first signal line of the circuit chip via the first pixel chip contact area (202) and the first circuit chip contact area (102).
[14] The solid-state imaging device of [13] described above, wherein the pixel chip (200) is stacked directly on the circuit chip (200).
[15] The solid-state imaging device of [13] described above, further comprising at least one chip (300) arranged between the pixel chip and the circuit chip.

1. A circuit chip, comprising:
a first circuit chip contact area configured to be electrically connected to a first pixel chip contact area of a pixel chip;
a first signal line electrically connected to the first circuit chip contact area;
a first comparator circuit, wherein the first signal line is electrically coupled to a first input of the first comparator circuit;
a first test circuit comprising a digital-to-analog converter circuit, the first test circuit being configured to output a test signal at an output of the first test circuit; and
a first switching element electrically coupled in series between the output of the first test circuit and the first signal line.

2. The circuit chip of claim 1, wherein the first switching element is operable to switch between electrically connecting the output of the first test circuit and the first signal line and electrically disconnecting the output of the first test circuit and the first signal line based on a first switching element input signal.

3. The circuit chip of claim 1, further comprising a test control circuit configured to generate and output the first switching element input signal to a control input of the first switching element, and wherein the test control circuit is further configured to generate and output a binary test signal to the digital-to-analog converter circuit of the first test circuit.

4. The circuit chip of claim 1, further comprising a first test chip contact area electrically coupled to a control input of the first switching element, and a second test chip contact area electrically coupled to the digital-to-analog converter circuit of the first test circuit.

5. The circuit chip of claim 1, further comprising:
a voltage ramp generator circuit comprising a second digital-to-analog converter circuit, wherein an output of the voltage ramp generator circuit is electrically connected to a second input of the first comparator circuit.

6. The circuit chip of claim 5, wherein more than 80% of a layout of the second digital-to-analog converter circuit is reused in the digital-to-analog converter circuit of the first test circuit.

7. The circuit chip claim 5, wherein the digital-to-analog converter circuit of the first test circuit is an n-bit digital-to-analog converter circuit, n ranging from 6 to 14.

8. The circuit chip of claim 7, wherein a layout area of the digital-to-analog converter circuit of the first test circuit ranges from 5% to 20% of a layout area of the second digital-to-analog converter circuit.

9. The circuit chip of claim 1, further comprising:
a second circuit chip contact area configured to be electrically connected to a second pixel chip contact area of the pixel chip;
a second signal line electrically connected to the second circuit chip contact area;
a second comparator circuit, wherein the second signal line is electrically coupled to a first input of the second comparator circuit;
a second test circuit comprising an output; and
a second switching element electrically coupled in series between the output of the second test circuit and the second signal line.

10. The circuit chip of claim 9, further comprising
a first number of circuit chip contact areas laterally arranged between the first chip contact area and the second chip contact area, wherein the first number ranges from ⅛ of a total number of the signal lines to the total number of the signal lines, wherein each of the first number of circuit chip contact areas is electrically coupled to the first test circuit.

11. The circuit chip of claim 1, further comprising
a third test circuit comprising a resistive divider circuit, the third test circuit being configured to output a test signal at an output of the third test circuit.

12. The circuit chip of claim 11, further comprising
a switch array circuit electrically coupled in series between the output of the third test circuit and the first switching element.

13. A solid-state imaging device, comprising:
the circuit chip of claim 1; and
the pixel chip stacked over the circuit chip, wherein the pixel chip includes a plurality of pixel circuits arranged in a matrix pattern, and a first vertical signal line, wherein a group of the plurality of pixel circuits is electrically coupled to the first vertical signal line, and the first vertical signal is electrically connected to the first signal line of the circuit chip via the first pixel chip contact area and the first circuit chip contact area.

14. The solid-state imaging device of claim 13, wherein the pixel chip is stacked directly on the circuit chip.

15. The solid-state imaging device of claim 13, further comprising at least one chip arranged between the pixel chip and the circuit chip.
